(19) United States
(12) Patent Application Publication
(10) Pub. No.: US 2010/0288355 A1
(43) Pub. Date: Nov. 18, 2010

(54) SILICON NITRIDE DIFFUSION BARRIER LAYER FOR CADMIUM STANNATE TCO

(75) Inventors: Scott Mills, Perrysburg, OH (US); Dale Roberts, Temperance, MI (US); Zhibo Zhao, Novi, MI (US); Yu Yang, Perrysburg, OH (US)

Correspondence Address: STEPTOE & JOHNSON LLP, 1330 CONNECTICUT AVENUE, N.W., WASHINGTON, DC, 20036, US

(73) Assignee: First Solar, Inc., Perrysburg, OH (US)

(21) Appl. No.: 12/782,546

(22) Filed: May 18, 2010

Related U.S. Application Data
(60) Provisional application No. 61/179,298, filed on May 18, 2009.

(51) Int. Cl. H01L 31/0224; H01L 29/43; H01L 31/18; H01L 21/283

(52) U.S. Cl. 136/256; 257/751; 438/98; 438/609; 257/E21.159; 257/E29.139; 257/E31.126

(57) ABSTRACT

A photovoltaic device can include a transparent conductive oxide layer adjacent to a substrate and a barrier layer, which can include a silicon-containing material.

### CLAIM FOR PRIORITY

This application claims priority under 35 U.S.C. §119(e) to U.S. Provisional Patent Application Ser. No. 61/179,298 filed on May 18, 2009, which is hereby incorporated by reference.

### TECHNICAL FIELD

The present invention relates to photovoltaic devices and methods of production.

### BACKGROUND

Photovoltaic devices can include semiconductor material deposited over a substrate, for example, with a first layer serving as a window layer and a second layer serving as an absorber layer. The semiconductor window layer can allow the penetration of solar radiation to the absorber layer, such as a cadmium telluride layer, which converts solar energy to electricity. Photovoltaic devices can also contain one or more transparent conductive oxide layers, which are also often conductors of electrical charge.

### DESCRIPTION OF DRAWINGS

FIG. 1 is a schematic of a photovoltaic device having multiple layers.

FIG. 2 is a schematic of a photovoltaic device having multiple layers.

FIG. 3 is a schematic of a photovoltaic device having multiple layers.

FIG. 4 is a schematic of a photovoltaic device having multiple layers.

### DETAILED DESCRIPTION

Photovoltaic devices can include multiple layers created on a substrate (or superstrate). For example, a photovoltaic device can include a barrier layer, a transparent conductive oxide (TCO) layer, a buffer layer, and a semiconductor layer formed in a stack on a substrate. Each layer may in turn include more than one layer or film. For example, the semiconductor layer can include a first film including a semiconductor window layer, such as a cadmium sulfide layer, formed on the buffer layer and a second film including a semiconductor absorber layer, such as a cadmium telluride layer formed on the semiconductor window layer. Additionally, each layer can cover all or a portion of the device and/or all or a portion of the layer or substrate underlying the layer. For example, a “layer” can include any amount of any material that contacts all or a portion of a surface.

Various suitable substrate materials are available for use in photovoltaic devices, including but not limited to, barosilicate, sapphire, sintered alumina, and soda-lime glass. Chemicals from these substrates can diffuse into device layers, degrading performance. This occurrence is common among devices with soda-lime glass substrates. Soda-lime glass contains large amounts of sodium, which is mobile and can migrate from the glass to the device layers, causing degradation and delamination. To prevent the diffusion of sodium and other similar unwanted chemicals, a barrier layer can be incorporated as part of a transparent conductive oxide stack. The barrier layer should be highly transparent, thermally stable, pin-hole free, and have good adhesion to the other stack materials.

A variety of barrier materials may be included in the TCO stack, including a silicon oxide and/or a silicon nitride. The TCO stack can include a silicon nitride, silicon oxide, aluminum-doped silicon oxide, boron-doped silicon nitride, phosphorus-doped silicon nitride, silicon oxide-nitride, or any combination or alloy thereof. The dopant can be less than 25%, less than 20%, less than 15%, less than 10%, less than 5% or less than 2%. The TCO stack may include multiple barrier materials. For example, the TCO stack can include a barrier bi-layer consisting essentially of a silicon oxide deposited over a silicon nitride (or an aluminum-doped silicon nitride). The barrier bi-layer can be optimized using optical modeling to achieve both color suppression and reduced reflection loss, though in practice a thicker bi-layer may be needed to block sodium more effectively.

The TCO stack can be manufactured using a variety of deposition techniques, including for example, low pressure chemical vapor deposition, atmospheric pressure chemical vapor deposition, plasma-enhanced chemical vapor deposition, thermal chemical vapor deposition, DC or AC sputtering, spin-on deposition, and spray-pyrolysis. Each deposition layer can be of any suitable thickness, for example in the range of about 1 to about 5000A.

In one aspect, a photovoltaic device can include a transparent conductive oxide layer adjacent to a substrate. The transparent conductive oxide layer can include a cadmium stannate. The photovoltaic device can include a barrier layer positioned between the substrate and the transparent conductive oxide layer. The barrier layer can include a silicon-containing material. The photovoltaic device can include a semiconductor bi-layer adjacent to the transparent conductive oxide layer. The semiconductor bi-layer can include a semiconductor absorber layer adjacent to a semiconductor window layer. The photovoltaic device can include a back contact adjacent to the semiconductor bi-layer.

The silicon-containing material can include a silicon nitride. The silicon-containing material can include a silicon nitride, aluminum-doped silicon nitride, silicon oxide, aluminum-doped silicon oxide, boron-doped silicon nitride, phosphorous-doped silicon nitride, silicon oxide-nitride, or tin oxide. The barrier material can include multiple layers. Each layer may include a silicon nitride, aluminum-doped silicon nitride, silicon oxide, aluminum-doped silicon oxide, boron-doped silicon nitride, phosphorous-doped silicon nitride, silicon oxide-nitride, or tin oxide. One of the layers may have a chemical composition that is distinct from that of another layer of the multiple layers. The substrate can include a glass. The glass can include a soda-lime glass. The semiconductor absorber layer can include a cadmium telluride layer. The semiconductor window layer can include a cadmium sulfide layer. The device can include a buffer layer between the transparent conductive oxide layer and the semiconductor bi-layer. The buffer layer can include a zinc tin oxide, tin oxide, zinc oxide, or zinc magnesium oxide. The barrier layer can have a thickness of about 1 to about 5000A. The barrier layer can include multiple barrier layers. The device can include a back support adjacent to the back contact.

In one aspect, a multi-layered substrate can include a transparent conductive oxide layer adjacent to a first substrate. The transparent conductive oxide layer can include a cadmium stannate. The multi-layered structure can include a barrier layer positioned between the first substrate and the transparent conductive oxide layer. The barrier layer can include a silicon-containing material.

The silicon-containing material can include a silicon nitride. The silicon-containing material can include a silicon nitride, aluminum-doped silicon nitride, silicon oxide, aluminum-doped silicon oxide, boron-doped silicon nitride, phosphorous-doped silicon nitride, silicon oxide-nitride, or tin oxide. The barrier material can include multiple layers. Each layer can include a silicon nitride, aluminum-doped silicon nitride, silicon oxide, aluminum-doped silicon oxide, boron-doped silicon nitride, phosphorous-doped silicon nitride, silicon oxide-nitride, or tin oxide. One of the layers can have a chemical composition that is distinct from that of another layer of the multiple layers. The first substrate can include a glass. The glass can include a soda-lime glass. The multi-layered substrate can include a buffer layer adjacent to the transparent conductive oxide layer. The buffer layer can include zinc tin oxide, tin oxide, zinc oxide, and zinc magnesium oxide. The barrier layer can have a thickness of about 1 to about 5000A. The barrier layer can include multiple barrier layers.

In one aspect, a method for manufacturing a photovoltaic device can include forming a transparent conductive oxide stack on a substrate. The forming can include depositing a transparent conductive oxide layer adjacent to a barrier layer. The barrier layer can include a silicon-containing material. The method can include depositing a semiconductor window layer adjacent to the transparent conductive oxide stack. The method can include depositing a semiconductor absorber layer adjacent to the semiconductor window layer.

The silicon-containing material can include a silicon nitride. The silicon-containing material can include a silicon nitride, aluminum-doped silicon nitride, silicon oxide, aluminum-doped silicon oxide, boron-doped silicon nitride, phosphorous-doped silicon nitride, silicon oxide-nitride, or tin oxide. The barrier material can include multiple layers. Each layer may include a silicon nitride, aluminum-doped silicon nitride, silicon oxide, aluminum-doped silicon oxide, boron-doped silicon nitride, phosphorous-doped silicon nitride, silicon oxide-nitride, or tin oxide. One of the layers may have a chemical composition that is distinct from that of another layer of the multiple layers. The method can include depositing the barrier layer on a substrate using a chemical vapor deposition process. Depositing a transparent conductive oxide layer adjacent to a barrier layer can include sputtering a cadmium stannate onto a silicon nitride. Depositing the transparent conductive oxide stack adjacent to a substrate can include placing a cadmium stannate onto a glass. Depositing a cadmium stannate onto a glass can include placing the cadmium stannate onto a soda-lime glass. Forming a transparent conductive oxide stack can include depositing a buffer layer adjacent to the transparent conductive oxide layer. The buffer layer can include a zinc tin oxide, tin oxide, zinc oxide, or zinc magnesium oxide. The method can include annealing the transparent conductive oxide stack. Annealing the transparent conductive oxide stack can include heating the transparent conductive oxide stack under reduced pressure. Annealing the transparent conductive oxide stack can include heating the transparent conductive oxide stack at about 400° C. to about 800° C., or at about 500° C. to about 700° C. Annealing the transparent conductive oxide stack can include heating the transparent conductive oxide stack for about 10 to about 25 minutes, or for about 15 to about 20 minutes.

Depositing a semiconductor window layer adjacent to the transparent conductive oxide stack can include placing a cadmium sulfide layer onto the transparent conductive oxide stack. Depositing a semiconductor window layer adjacent to the transparent conductive oxide stack can include transporting a vapor. Depositing a semiconductor absorber layer adjacent to the semiconductor window layer can include placing a cadmium telluride layer on a substrate. Depositing a semiconductor absorber layer adjacent to the semiconductor window layer can include transporting a vapor. Depositing a transparent conductive oxide layer adjacent to a barrier layer can include depositing the transparent conductive oxide layer adjacent to multiple barrier layers. The method can include depositing a back contact adjacent to the semiconductor absorber layer, and a back support adjacent to the back contact.

In one aspect, a method for manufacturing a multi-layered substrate can include forming a transparent conductive oxide stack on a first substrate. The forming can include depositing a transparent conductive oxide layer adjacent to a barrier layer. The barrier layer can include a silicon-containing material.

The silicon-containing material can be a silicon nitride. The silicon-containing material can be a silicon nitride, aluminum-doped silicon nitride, silicon oxide, aluminum-doped silicon oxide, boron-doped silicon nitride, phosphorous-doped silicon nitride, silicon oxide-nitride, or tin oxide. The barrier material can include multiple layers. Each layer can include a silicon nitride, aluminum-doped silicon nitride, silicon oxide, aluminum-doped silicon oxide, boron-doped silicon nitride, phosphorous-doped silicon nitride, silicon oxide-nitride, or tin oxide. One of the layers may have a chemical composition that is distinct from that of another layer of the multiple layers. The method can include depositing the barrier layer on the first substrate using a chemical vapor deposition process. Depositing a transparent conductive oxide layer adjacent to a barrier layer can include sputtering a cadmium stannate onto a silicon nitride. Depositing the transparent conductive oxide stack adjacent to a first substrate can include placing a cadmium stannate onto a glass. Placing a cadmium stannate onto a glass can include placing the cadmium stannate onto a soda-lime glass. Forming a transparent conductive oxide stack can include depositing a buffer layer adjacent to the transparent conductive oxide layer. The buffer layer can include a zinc tin oxide, tin oxide, zinc oxide, or zinc magnesium oxide. The method can include annealing the transparent conductive oxide stack. Annealing the transparent conductive oxide stack can include heating the transparent conductive oxide stack under reduced pressure. Annealing the transparent conductive oxide stack can include heating the transparent conductive oxide stack at about 400° C. to about 800° C. Annealing the transparent conductive oxide stack can include heating the transparent conductive oxide stack at about 500° C. to about 700° C. Annealing the transparent conductive oxide stack can include heating the transparent conductive oxide stack for about 10 to about 25 minutes. Annealing the transparent conductive oxide stack can include heating the transparent conductive oxide stack for about 15 minutes to about 20 minutes. Depositing a transparent conductive oxide layer adjacent to a barrier layer can include depositing the transparent conductive oxide layer adjacent to multiple barrier layers.

In one aspect, a method for manufacturing a sputter target can include distributing cadmium and tin substantially throughout the target. The target may be configured to have atoms dislodged or ejected from therein to form a transparent conductive oxide stack on a substrate. The forming can include depositing a transparent conductive oxide layer adjacent to a barrier layer. The barrier layer can include a silicon-containing material.

The step of distributing cadmium and tin substantially throughout the target can include stoichiometrically distributing cadmium and tin. The method can include placing the cadmium and tin in a cast. The cast can be configured to cast the target into a tube shape. The step of distributing cadmium and tin substantially throughout the target can include forming a piece including cadmium. The step of distributing cadmium and tin substantially throughout the target can include forming a piece including tin. The step of distributing cadmium and tin substantially throughout the target can include connecting the two pieces to form the target. Each piece can be formed by casting. The two pieces can be sleeve-shaped. The two pieces can be connected by welding. The step of distributing cadmium and tin substantially throughout the target can include consolidating cadmium powder and tin powder to form the target. The step of consolidating cadmium powder and tin powder can include pressing the powders. The step of pressing the powders can include isostatically pressing the powders. The step of distributing cadmium and tin substantially throughout the target can include positioning a wire including cadmium and tin adjacent to a base. The step of positioning a wire including cadmium and tin adjacent to a base can include wrapping the wire around the base. The base can include a tube. The method can include pressing the wire. The step of pressing the wire can include isostatically pressing the wire. The step of distributing cadmium and tin substantially throughout the target can include spraying cadmium and tin onto a base. The step of spraying cadmium and tin onto a base can include thermal spraying cadmium and tin.

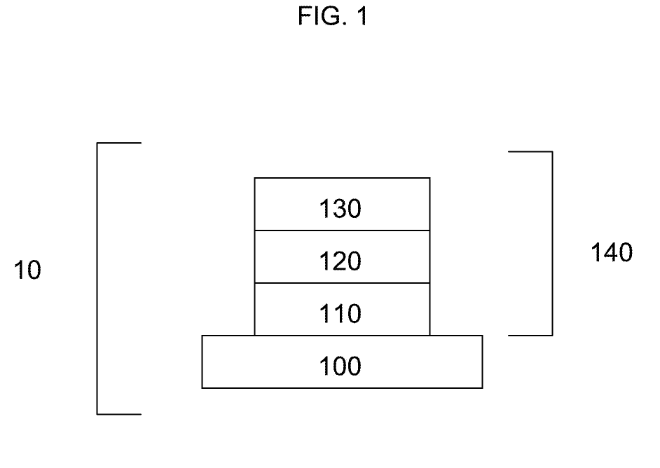

Referring to FIG. 1, a photovoltaic device 10 can include a transparent conductive oxide layer 120 deposited adjacent to a barrier layer 110, which can include any of the barrier materials mentioned above silicon nitride. Transparent conductive layer 120 can include a cadmium stannate, and can be deposited adjacent to substrate 100, such that barrier layer 110 is positioned between transparent conductive oxide layer 120 and substrate 100. Barrier layer 110 can prevent sodium from diffusing from soda-lime glass substrate 100 into transparent conductive oxide layer 120. Barrier layer 110 can be deposited through any known deposition technique, including sputtering and any appropriate chemical vapor deposition (CVD) process, such as LPCVD, APCVD, PECVD, or thermal CVD. The barrier layer(s) can be of any suitable thickness, including about 1 to about 5000A. Substrate 100 can include any suitable material, including a glass, for example a soda-lime glass.

In continuing reference to FIG. 1, transparent conductive oxide layer 120 and barrier layer 110 can be part of a transparent conductive oxide stack 140, which can also include a buffer layer 130. Buffer layer 130 can provide a surface onto which subsequent layers can be deposited, adjacent to transparent conductive oxide layer 120. Buffer layer 130 can be deposited using any suitable deposition technique, including sputtering and can include any suitable material, such as zinc tin oxide, tin oxide, zinc oxide, and zinc magnesium oxide. Transparent conductive oxide stack 140 can be formed on substrate 100. Alternatively, substrate 100 can be obtained with transparent conductive oxide stack 140 preassembled on top, allowing for deposition of device layers thereon.

In one example, transparent conductive oxide layer 120 can include a cadmium stannate film created from sputtering a target and can contain stoichiometric amounts of metal oxides, such as tin oxide and cadmium oxide onto a substrate. The sputtering can be conducted in oxygen, which is substantially free of impurities which could react with the metal oxides present. During reactive sputtering, an optimum oxygen concentration can be from 56-58%, for example. The sputtering can be performed at room temperature. The sputtering process can include dislodging or ejecting material (e.g., atoms) from a metallic target, cadmium target, tin target, or target including both cadmium and tin. The target can be a tube or plate. As deposited by sputtering, transparent conductive layer is substantially amorphous. As is apparent to one skilled in the art, higher transmittance is obtained with a thinner film, and lower sheet resistivity is obtained with a thicker film. Applicants have found that varying the concentration of a metal oxide in the film has resulted in maximum carrier concentration and minimum film resistivity, and therefore, increased conductivity.

In one example, a sputtering target can include cadmium and tin in a weight ratio greater than 2.15:1, greater than 2.2:1, greater than 2.4:1, less than 2.6:1, or less than 3:1 distributed substantially uniformly throughout the target. A sputtering target can be cadmium and tin manufactured, formed, and/or shaped by any process and in any shape, composition, or configuration suitable for use with any appropriate sputtering tool, machine, apparatus, or system.

A sputtering target can be manufactured by ingot metallurgy. A sputtering target can be manufactured from cadmium, from tin, or from both cadmium and tin. The cadmium and tin can be present in the same target in stoichiometrically proper amounts. A sputtering target can be manufactured as a single piece in any suitable shape. A sputtering target can be a tube. A sputtering target can be manufactured by casting a metallic material into any suitable shape, such as a tube.

A sputtering target can be manufactured from more than one piece. A sputtering target can be manufactured from more than one piece of metal, for example, a piece of cadmium and a piece of tin. The cadmium and tin can be manufactured in any suitable shape, such as sleeves, and can be joined or connected in any suitable manner or configuration. For example, a piece of cadmium and a piece of tin can be welded together to form the sputtering target. One sleeve can be positioned within another sleeve.

A sputtering target can be manufactured by powder metallurgy. A sputtering target can be formed by consolidating metallic powder (e.g., cadmium or tin powder) to form the target. The metallic powder can be consolidated in any suitable process (e.g., pressing such as isostatic pressing) and in any suitable shape. The consolidating can occur at any suitable temperature. A sputtering target can be formed from metallic powder including more than one metal powder (e.g., cadmium and tin). More than one metallic powder can be present in stoichiometrically proper amounts.

A sputter target can be manufactured by positioning wire including target material adjacent to a base. For example wire including target material can be wrapped around a base tube. The wire can include multiple metals (e.g., cadmium and tin) present in stoichiometrically proper amounts. The base tube can be formed from a material that will not be sputtered. The wire can be pressed (e.g., by isostatic pressing).

A sputter target can be manufactured by spraying a target material onto a base. Metallic target material can be sprayed by any suitable spraying process, including thermal spraying and plasma spraying. The metallic target material can include multiple metals (e.g., cadmium and tin), present in stoichiometrically proper amounts. The base onto which the metallic target material is sprayed can be a tube.

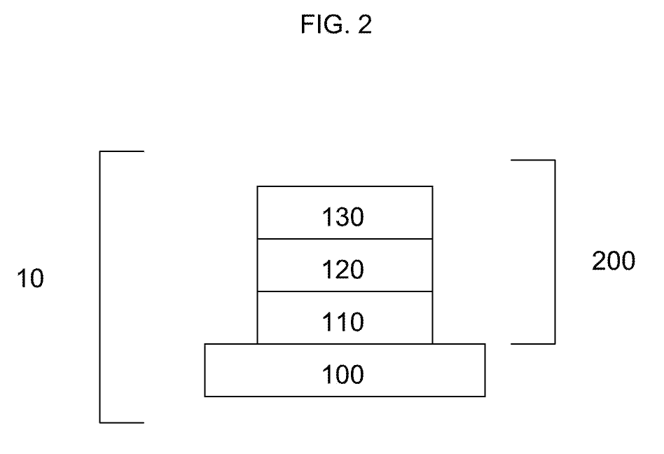

Referring to FIGS. 1 and 2, transparent conductive oxide stack 140 from FIG. 1 can be annealed to form an annealed transparent conductive oxide stack 200. The annealing can occur under any suitable conditions. Transparent conductive oxide stack 140 can be annealed at any suitable pressure. For example, transparent conductive oxide stack 140 can be annealed under reduced pressure, pressure less than atmospheric pressure, or under a substantial vacuum. Transparent conductive oxide stack 140 can be annealed at any suitable temperature or temperature range. For example, transparent conductive oxide stack 140 can be annealed at about 400° C. to about 800° C. Transparent conductive oxide stack 140 can be annealed at about 500° C. to about 700° C. The annealing can occur in the presence of a gas selected to control an aspect of the annealing, for example zinc. Transparent conductive oxide stack 140 can be annealed for any suitable duration. For example, transparent conductive oxide stack 140 can be annealed for about 10 to about 25 minutes. Transparent conductive oxide stack 140 can be annealed for about 15 to about 20 minutes. Annealing transparent conductive oxide stack 140 from FIG. 1 can provide annealed transparent conductive oxide stack 200 from FIG. 2.

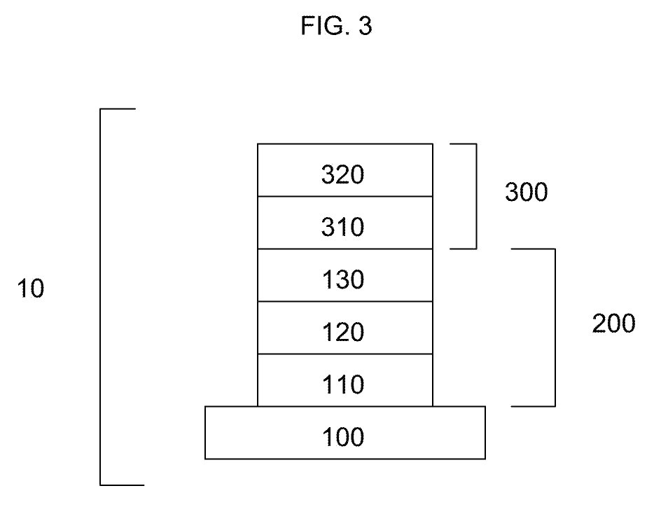

Referring to FIG. 3, semiconductor bi-layer 300 can be formed adjacent to annealed transparent conductive oxide stack 200. Semiconductor bi-layer 300 can be formed on annealed transparent conductive oxide stack 200. Semiconductor bi-layer 300 can include semiconductor window layer 310 and semiconductor absorber layer 320. Semiconductor window layer 310 of semiconductor bi-layer 300 can be deposited adjacent to annealed transparent conductive oxide stack 200. Semiconductor window layer 310 can include any suitable window material, such as cadmium sulfide, and can be formed by any suitable deposition method, such as vapor transport deposition. Semiconductor absorber layer 320 can be deposited adjacent to semiconductor window layer 310. Semiconductor absorber layer 320 can be deposited on semiconductor window layer 310. Semiconductor absorber layer 320 can be any suitable absorber material, such as cadmium telluride, and can be formed by any suitable method such as vapor transport deposition.

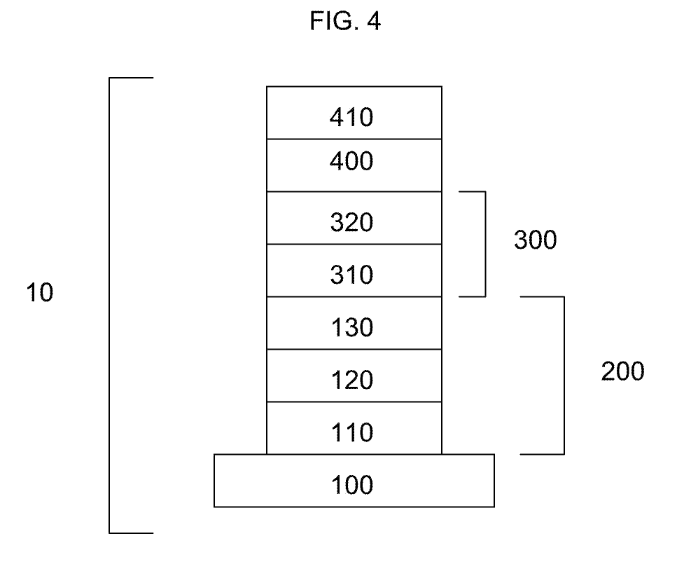

Referring to FIG. 4, a back contact 400 can be deposited adjacent to semiconductor absorber layer 320. Back contact 400 can be deposited adjacent to semiconductor bi-layer 300. Back contact 400 can include any suitable material, including a metal. A back support 410 can be positioned adjacent to back contact 400.

In one experiment, the efficiency of device structures with silicon nitride and silicon dioxide barriers was tested. Layers of cadmium stannate were deposited onto layers of either silicon nitride or silicon dioxide. Tin oxide buffer layers with process voltage from 500 to 620 V, were deposited onto the cadmium stannate to form stacks. Half of the stacks were annealed at 600° C. for about 17 minutes. Layers of cadmium sulfide and cadmium telluride were then deposited onto both sets of stacks. These device structures were compared with a conventional non-sputtered transparent conductive oxide coated substrate, which included a cadmium sulfide-cadmium telluride bi-layer. The annealed stacks with silicon nitride barriers and low voltage buffers showed an efficiency between 10-12%, which was comparable to that demonstrated by the conventional device. Results also showed that for devices formed with silicon nitride barrier layers, cadmium sulfide distribution was continuous, uninterrupted, and uniform.

In another experiment, various barrier materials were tested against the conventional device for sodium content and dot cell efficiency. Stacks were formed using silicon dioxide, tin(IV) oxide, tin(IV) oxide+silicon dioxide, and silicon nitride barrier layers. Secondary ion mass spectroscopy (SIMS) was used to analyze sodium content in the resulting cadmium telluride devices. Sodium content was lowest in the silicon nitride stacks. These stacks also demonstrated high efficiencies, in the 12% range, which was again comparable to those demonstrated by the conventional device. Results also indicated that as sodium content decreased, dot cell efficiency increased, demonstrating sodium's adverse effect on device performance.

In another experiment, stacks were formed on various substrate materials and tested. Results indicated that stacks formed on sodium-free glass showed high efficiency, likely a result of low sodium diffusion. Stacks formed on sodium-free glass without a sodium barrier were the most efficient, with efficiencies around 12%, likely due to the absorption lost from the barrier layer. However, stacks formed on soda-lime glass with a silicon nitride barrier showed comparable efficiency, in the 11% range. Results also indicated higher values for open circuit voltage (over 800 V), fill factor (65-70%), and short circuit resistance, and lower values for short circuit current density and open circuit resistance (6-8 ohms/sq). Experiments also indicated that increasing sodium content negatively affected device efficiency.

In another experiment, the impact of cadmium chloride treatment was analyzed. Stacks were formed using the conventional configuration, and others using sodium-free, aged soda-lime, and tin-sided soda lime glass substrates, some with silicon nitride barrier layers and some without. A portion of the stacks were treated with cadmium chloride. Results indicated that for the stacks formed on soda-lime glass, cadmium chloride treatment had the effect of increasing sodium content by a factor of 40. The result of this increased sodium content was a reduced efficiency—less than 10%.

The embodiments described above are offered by way of illustration and example. It should be understood that the examples provided above may be altered in certain respects and still remain within the scope of the claims. It should be appreciated that, while the invention has been described with reference to the above preferred embodiments, other embodiments are within the scope of the claims.

What is claimed is:

1. A photovoltaic device, comprising:
a transparent conductive oxide layer adjacent to a substrate, the transparent conductive oxide layer comprising a cadmium stannate;
a barrier layer positioned between the substrate and the transparent conductive oxide layer, the barrier layer comprising a silicon-containing material;
a semiconductor bi-layer adjacent to the transparent conductive oxide layer, the semiconductor bi-layer comprising a semiconductor absorber layer adjacent to a semiconductor window layer; and
a back contact adjacent to the semiconductor bi-layer.

2. The photovoltaic device of claim 1, wherein the silicon-containing material is a silicon nitride, aluminum-doped silicon nitride, silicon oxide, aluminum-doped silicon oxide, boron-doped silicon nitride, phosphorous-doped silicon nitride, silicon oxide-nitride, or tin oxide.

3. The photovoltaic device of claim 1, wherein the barrier material comprises multiple layers, wherein each layer is selected from the group consisting of silicon nitride, aluminum-doped silicon nitride, silicon oxide, aluminum-doped silicon oxide, boron-doped silicon nitride, phosphorous-doped silicon nitride, silicon oxide-nitride, and tin oxide, and wherein one of the layers has a chemical composition that is distinct from that of another layer of the multiple layers.

4. The photovoltaic device of claim 1, wherein the barrier layer has a thickness of about 1 to about 5000A.

5. The photovoltaic device of claim 1, wherein the barrier layer comprises multiple barrier layers.

6. A multi-layered substrate comprising:
a transparent conductive oxide layer adjacent to a first substrate, the transparent conductive oxide layer comprising a cadmium stannate;
a barrier layer positioned between the first substrate and the transparent conductive oxide layer, the barrier layer comprising a silicon-containing material.

7. The multi-layered substrate of claim 6, wherein the silicon-containing material is a silicon nitride, aluminum-doped silicon nitride, silicon oxide, aluminum-doped silicon oxide, boron-doped silicon nitride, phosphorous-doped silicon nitride, silicon oxide-nitride, or tin oxide.

8. The multi-layered substrate of claim 6, wherein the barrier material comprises multiple layers, wherein each layer is selected from the group consisting of silicon nitride, aluminum-doped silicon nitride, silicon oxide, aluminum-doped silicon oxide, boron-doped silicon nitride, phosphorous-doped silicon nitride, silicon oxide-nitride, and tin oxide, and wherein one of the layers has a chemical composition that is distinct from that of another layer of the multiple layers.

9. The multi-layered substrate of claim 6, wherein the barrier layer has a thickness of about 1 to about 5000A.

10. The multi-layered substrate of claim 6, wherein the barrier layer comprises multiple barrier layers.

11. A method for manufacturing a photovoltaic device, the method comprising:
forming a transparent conductive oxide stack on a substrate, wherein the forming comprises depositing a transparent conductive oxide layer adjacent to a barrier layer, the barrier layer comprising a silicon-containing material;
depositing a semiconductor window layer adjacent to the transparent conductive oxide stack; and
depositing a semiconductor absorber layer adjacent to the semiconductor window layer.

12. The method of claim 11, further comprising depositing the barrier layer on a substrate using a chemical vapor deposition process.

13. The method of claim 11, further comprising annealing the transparent conductive oxide stack.

14. The method of claim 13, wherein annealing the transparent conductive oxide stack comprises heating the transparent conductive oxide stack under reduced pressure.

15. The method of claim 13, wherein annealing the transparent conductive oxide stack comprises heating the transparent conductive oxide stack at about 400° C. to about 800° C.

16. The method of claim 13, wherein annealing the transparent conductive oxide stack comprises heating the transparent conductive oxide stack for about 10 to about 25 minutes.

17. A method for manufacturing a multi-layered substrate, the method comprising:
forming a transparent conductive oxide stack on a first substrate, wherein the forming comprises depositing a transparent conductive oxide layer adjacent to a barrier layer, the barrier layer comprising a silicon-containing material.

18. The method of claim 17, further comprising depositing the barrier layer on the first substrate using a chemical vapor deposition process.

19. The method of claim 17, further comprising annealing the transparent conductive oxide stack.

20. The method of claim 19, wherein annealing the transparent conductive oxide stack comprises heating the transparent conductive oxide stack under reduced pressure.

21. The method of claim 19, wherein annealing the transparent conductive oxide stack comprises heating the transparent conductive oxide stack at about 400° C. to about 800° C.

22. The method of claim 19, wherein annealing the transparent conductive oxide stack comprises heating the transparent conductive oxide stack for about 10 to about 25 minutes.
